(19) United States
(12) Patent Application Publication
(10) Pub. No.: US 2006/0094235 A1
(43) Pub. Date: May 4, 2006

(54) Method for fabricating gate electrode in semiconductor device

(75) Inventors: Hae-Jung Lee, Ichon-shi (KR); Jae-Seon Yu, Ichon-shi (KR); Phil-Goo Kong, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Ichon-shi (KR)

(21) Appl. No.: 11/150,644

(22) Filed: Jun. 10, 2005

(30) Foreign Application Priority Data
Oct. 30, 2004 (KR) 10-2004-0087693

(51) Int. Cl. H01L 21/4763; H01L 21/302

(52) U.S. Cl. 438/649; 438/736

(57) ABSTRACT

Disclosed is a method for fabricating a gate electrode in a semiconductor device. The method includes the steps of: forming a plurality of trenches on a substrate in a cell region; sequentially forming a gate oxide layer, a polysilicon layer, a metal silicide layer and an insulation layer for a hard mask on the substrate; forming a mask pattern for forming the gate electrode on the insulation layer; forming a hard mask pattern by etching the insulation layer by using the mask pattern as an etch mask; removing the mask pattern; etching the metal silicide layer by using the hard mask pattern until the polysilicon layer is exposed in the peripheral region; etching the polysilicon layer by using a gas including chlorine (Cl₂), nitrogen (N₂) and helium (He) until the gate oxide layer is exposed in the peripheral region; and etching the polysilicon layer remained in the cell region.

### CROSS-REFERENCES TO RELATED APPLICATIONS

The present application claims priority to Korean Application Serial No. 10-2004-0087693, filed on Oct. 30, 2004, which is incorporated by reference.

### BACKGROUND OF THE INVENTION

1. Field of the Invention

The present invention relates to a method for fabricating a semiconductor device; and more particularly, to a method for fabricating a gate electrode in a semiconductor device.

2. Description of the Related Art

As a scale of integration of a semiconductor device has decreased, a channel length of a transistor has shortened as well. If the channel length gets shorter, a problem of a short channel effect that a threshold voltage abruptly decreases is generated.

Accordingly, to increase the channel length of the gate, a trench is formed on a substrate and then, a gate electrode is formed on the trench, thereby increasing the channel length.

FIGS. 1A to 1E are cross-sectional views illustrating a conventional method for fabricating a gate electrode in a semiconductor device.

Referring to FIG. 1A, a field oxide layer 11 for a device isolation is formed on a substrate 10 divided into a cell region A and a peripheral region B. Subsequently, a sacrificial oxide layer 12 is formed on the substrate 10 and then, a first mask pattern 13 for forming a trench is formed on the sacrificial oxide layer 12.

Next, as shown in FIG. 1B, the substrate 10 is selectively etched by using the first mask pattern 13 as an etch mask, thereby forming a trench T. At this time, each lateral side of the trench T has a vertical profile.

Next, as shown in FIG. 1C, the first mask pattern 13 and the sacrificial mask 12 are sequentially removed. Afterwards, a gate oxide layer 14, a polysilicon layer 15, a metal silicide layer 16 and an insulation layer 17 for a hard mask are sequentially formed on an entire surface of the substrate 10 including the trench T. Subsequently, a second mask pattern 18 for forming a gate electrode is formed on the insulation layer 17 for the hard mask.

Next, as shown in FIG. 1D, the insulation layer 17 for the hard mask is selectively etched by using the second mask pattern 18 as an etch mask, thereby forming a hard mask 17A. Subsequently, the second mask pattern 18 is removed. Then, the metal silicide layer 16 is etched to expose the polysilicon layer 15 in the peripheral region B by performing a dry etch using a mixed gas of chlorine (Cl₂), nitrogen trifluoride (NH₃) and nitrogen (N₂) with use of the hard mask 17A as an etch mask.

At this time, although the etch performed to the metal silicide layer 16 in the peripheral region B having a small aspect ratio, the metal silicide layer 16 remains in the cell region A having a large aspect ratio. To remove the metal silicide layer 16 remained in the cell region A, an excessive etch is performed. The N₂ gas is added to minimize a difference in an etch selectivity between the cell region A and the peripheral region B and the NF₃ gas is added to etch the metal silicide layer 16 in a vertical shape.

Herein, since fluorine (F) element of the NF₃ gas has a low etch selectivity with respect to an oxide layer, a predetermined amount of the polysilicon layer 15 is compelled to be remained and the remaining polysilicon layer 15 should be typically equal to or more than approximately 50 Å. Accordingly, under this limited condition, since an amount that the metal silicide layer 16 is subjected to the excessive etch is not sufficient in an area where a height difference in the trench T exists, a residue R1 of the metal silicide layer 16 remains.

Next, as shown in FIG. 1E, the polysilicon layer 15 is selectively etched to expose the gate oxide layer 14 by performing a dry etch using a mixed gas of hydrogen bromide (HBr) and oxygen (O₂) with use of the hard mask 17A as an etch mask, thereby completing a gate pattern G1.

However, although an excessive etch is sufficiently performed to expose the gate oxide layer 14, a residue R2 of the polysilicon layer 15 remains on a bottom lateral side of the gate electrode pattern G1 because an etching speed of the metal silicide layer 16 with respect to the HBr gas is approximately 10% equal to or less than that of the polysilicon layer 15 with respect to the HBr gas.

In accordance with the gate electrode of the semiconductor device fabricated through the conventional method, a thickness of a gate conductive layer deposited in a boundary between one area where a substrate is etched and the other area where the substrate is not etched is differentiated due to a height difference in a lateral side of a trench T in a cell region during a metal silicide layer is deposited. Thus, after etching processes subjected to the conductive layer for forming a gate pattern and a polysilicon layer through a subsequent process are employed, a residue of the polysilicon layer remains in the trench T of the above boundary, thereby generating a problem in inducing an electric short between gate interconnection lines. This problem makes it difficult to increase a scale of integration of a device and brings a lack in a process margin.

### BRIEF SUMMARY OF THE INVENTION

It is, therefore, an object of the present invention to provide a method for fabricating a gate electrode in a semiconductor device capable of preventing a residue generated on a lateral side of the gate electrode.

In accordance with one aspect of the present invention, there is provided a method for fabricating a gate electrode, including the steps of: forming a plurality of trenches on a substrate in a cell region; sequentially forming a gate oxide layer, a polysilicon layer, a metal silicide layer and an insulation layer for a hard mask on the substrate; forming a mask pattern for forming the gate electrode on the insulation layer; forming a hard mask pattern by etching the insulation layer by using the mask pattern as an etch mask; removing the mask pattern; etching the metal silicide layer by using the hard mask pattern until the polysilicon layer is exposed in the peripheral region; etching the polysilicon layer by using a gas including chlorine (Cl₂), nitrogen (N₂) and helium (He) until the gate oxide layer is exposed in the peripheral region; and etching the polysilicon layer remained in the cell region.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1E are cross-sectional views illustrating a conventional method for fabricating a gate electrode in a semiconductor device; and

FIGS. 2A to 2E are cross-sectional views illustrating a method for fabricating a gate electrode in a semiconductor device in accordance with the present invention.

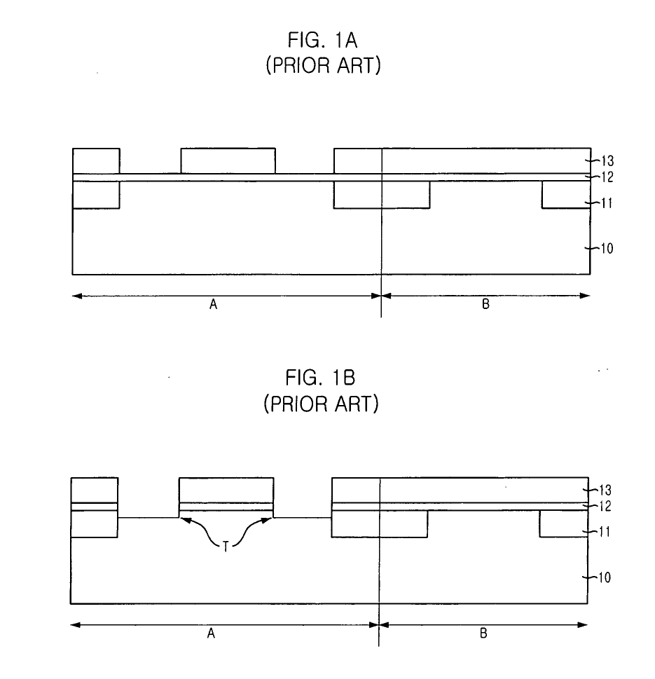

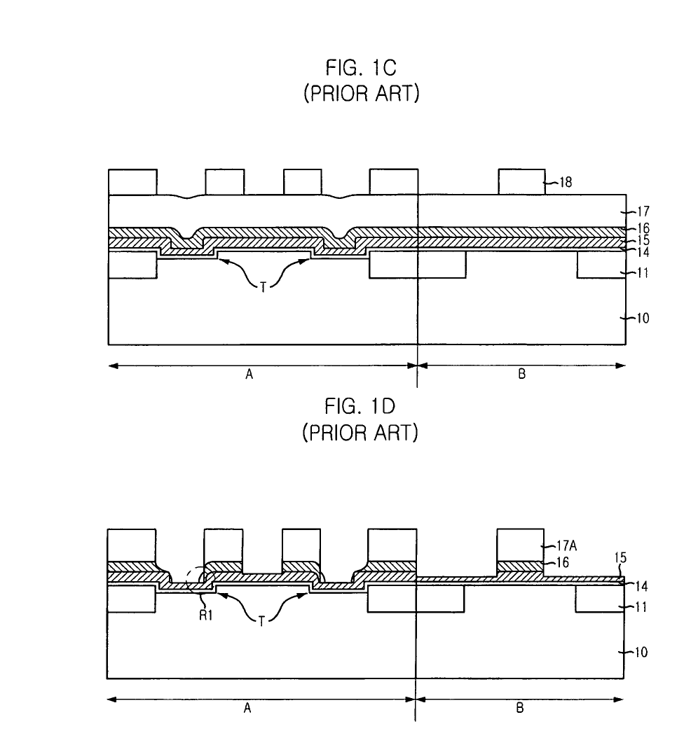

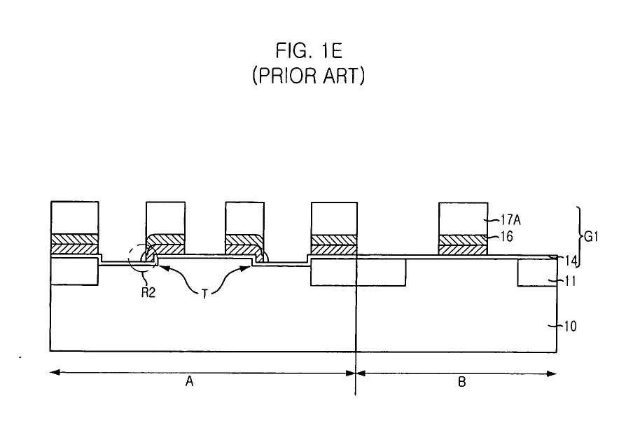

### DETAILED DESCRIPTION OF THE INVENTION

Hereinafter, detailed descriptions of preferred embodiments of the present invention will be provided with reference to the accompanying drawings.

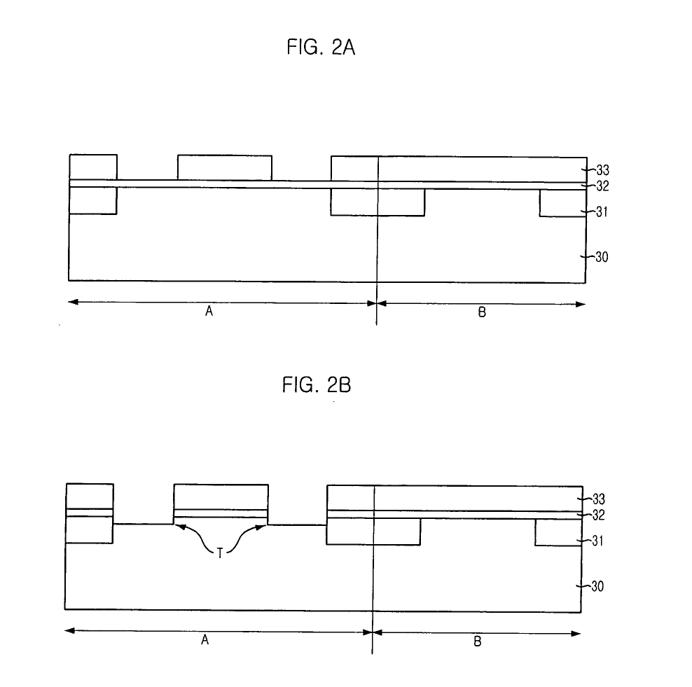

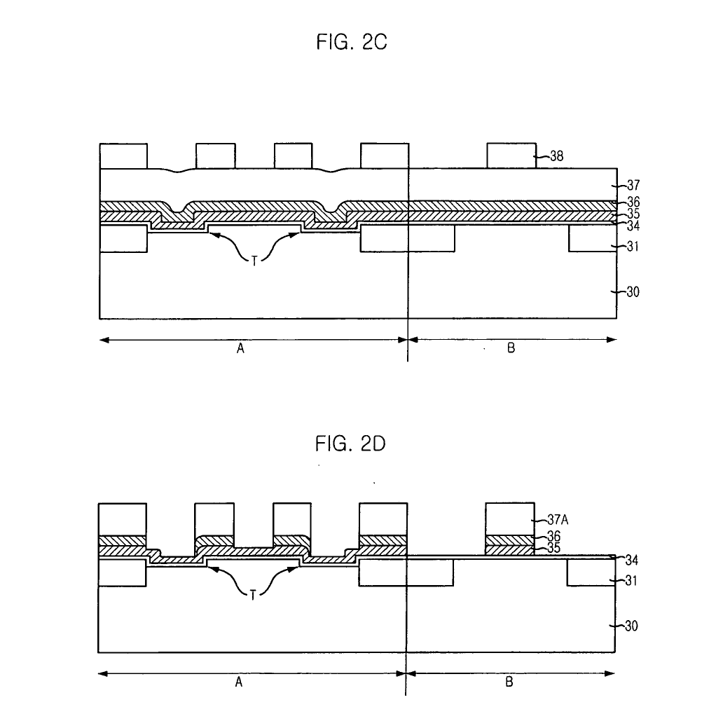

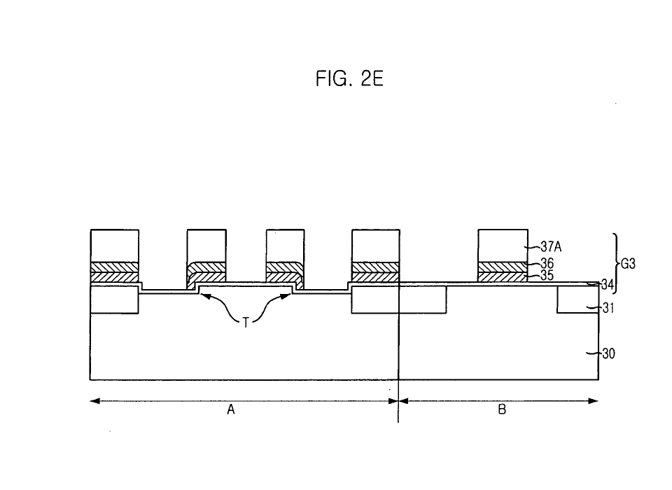

FIGS. 2A to 2E are cross-sectional views illustrating a method for fabricating a gate electrode in a semiconductor device in accordance with the present invention.

Referring to FIG. 2A, a field oxide layer 31 for isolating a device is formed on a substrate 30 including a cell region A and a peripheral region B. Subsequently, a sacrificial oxide layer 32 is formed on the substrate 30 and then, a first mask pattern 33 for forming a trench is formed on the sacrificial oxide layer 32.

Next, as shown in FIG. 2B, the substrate 30 is selectively etched by using the first mask pattern 33 as an etch mask, thereby forming a trench T. At this time, each lateral side of the trench T has a vertical profile.

Next, as shown in FIG. 2C, the first mask pattern 33 and the sacrificial oxide layer 32 are sequentially removed and afterwards, a gate oxide layer 34, a polysilicon layer 35, a metal silicide layer 36 and an insulation layer 37 for a hard mask are sequentially formed on an entire surface of the substrate 30 including the trench T. Subsequently, a second mask pattern 38 for forming a gate electrode is formed on the insulation layer 37 for the hard mask.

Next, as shown in FIG. 2D, the insulation layer 37 for the hard mask is selectively etched by using the second mask pattern 38 as an etch mask, thereby forming a hard mask 37A. Subsequently, the second mask pattern 38 is removed and then, the metal silicide layer 36 is etched until the polysilicon layer 35 in the peripheral region B is exposed by using the hard mask 37A as an etch mask through a dry etch employing a mixed gas of chlorine (Cl₂), nitrogen trifluoride (NF₃) and nitrogen (N₂). At this time, the metal silicide layer 36 remains in an area of the cell region A where the trench T is formed.

Next, the polysilicon layer 35 is selectively etched through an excessive etch by employing a gas including Cl₂, N₂ and helium (He) with use of the hard mask 37A as an etch mask until the gate oxide layer 34 is exposed in the peripheral region B through in-situ. The etch subjected to the polysilicon layer 35 is performed by employing Cl₂ ranging from approximately 50 sccm to approximately 150 sccm, N₂ ranging from approximately 5 sccm to 15 sccm and He ranging from approximately 100 sccm to approximately 300 sccm with use of a source power ranging from approximately 500 W to approximately 900 W and a bias power ranging from approximately 20 W to approximately 50 W in a chamber pressure ranging from approximately 10 mtorr to approximately 20 mtorr.

Herein, by adding He having a high etch selectivity with respect to an oxide layer instead of using NF₃ added to etch the polysilicon layer 35 in a vertical type, the gate oxide layer 34 is hardly damaged even though the gate oxide layer 34 is etched to be exposed. Also, in order to increase the etch selectivity with respect to the gate oxide layer 34, an oxygen (O₂) gas can be added more. At this time, since an amount that the metal silicide layer 36 is excessively etched is sufficient in an area where the height difference in the trench T is generated, it is possible to prevent a residue of the metal silicide layer 36 from being remained.

Next, as shown in FIG. 2E, the polysilicon layer 35 in the cell region A is selectively etched to expose the gate oxide layer 34 by performing a dry etch employing a mixed gas of hydrogen bromide (HBr) and O₂ with use of the hard mask 37A as an etch mask through the method of in-situ, thereby forming a gate electrode pattern G3.

In accordance with the present invention, it is possible to prevent a residue generated on a lateral side of a gate electrode pattern by excessively etching a polysilicon layer with use of He having a high etch selectivity with respect to a gate oxide layer, thereby achieving a high scale of integration and improving yields of products.

The present application contains subject matter related to the Korean patent application No. KR 2004-0087693, filed in the Korean Patent Office on Oct. 30, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. A method for fabricating a gate electrode, comprising:
forming a plurality of trenches over a substrate in a cell region, the substrate having the cell region and a peripheral region;
sequentially forming a gate oxide layer, a polysilicon layer, a metal silicide layer and an insulation layer over the substrate;
patterning the insulation layer to provide a plurality of first mask patterns provided in the cell region and a plurality of second mask patterns provided in the peripheral region;
etching the metal silicide layer by using the second mask patterns until the polysilicon layer is exposed in the peripheral region;
etching the exposed polysilicon layer in the peripheral region by using a first gas mixture at least until the gate oxide layer is exposed in the peripheral region; and
thereafter, etching the polysilicon layer remaining in the cell region by using a second gas mixture that is different from the first gas mixture.

2. The method of claim 1, wherein in the step of etching the polysilicon layer, the metal silicide layer remaining in the cell region is excessively etched.

3. The method of claim 1, wherein in the first gas mixture includes an oxygen (O₂) gas.

4. The method of claim 2, wherein the second gas mixture includes an O₂ gas.

5. The method of claim 1, wherein the first gas mixture includes Cl₂ ranging from approximately 50 sccm to approximately 150 sccm, N₂ ranging from approximately 5 sccm to approximately 15 sccm and He ranging from approximately 100 sccm to approximately 300 sccm.

6. The method of claim 2, wherein in the first gas mixture includes Cl₂ ranging from approximately 50 sccm to approximately 150 sccm, N₂ ranging from approximately 5 sccm to approximately 15 sccm and He ranging from approximately 100 sccm to approximately 300 sccm.

7. The method of claim 5, wherein in the step of etching the exposed polysilicon layer in the peripheral region, a source power ranging from approximately 500 W to approximately 900 W and a bias power ranging from approximately 20 W to approximately 50 W are used while maintaining a chamber pressure ranging from approximately 10 mtorr to approximately 20 mtorr.

8. The method of claim 6, wherein in the step of etching the exposed polysilicon layer in the peripheral region, a source power ranging from approximately 500 W to approximately 900 W and a bias power ranging from approximately 20 W to approximately 50 W are used along with maintaining a chamber pressure ranging from approximately 10 mtorr to approximately 20 mtorr.

9. The method of claim 1, wherein in the step of etching the metal silicide layer, a gas including Cl₂, NF₃ and N₂ is used.

10. The method of claim 1, wherein the metal silicide is etched using a third gas mixture that is different from the first and second gas mixtures.

11. The method of claim 1, wherein the step of etching the metal silicide layer and the polysilicon layer is performed in the identical chamber through a method of in-situ.

12. The method of claim 1, wherein the first gas mixture includes chlorine (Cl₂), nitrogen (N₂) and helium (He).

13. The method of claim 12, wherein helium is provided in the first gas mixture to a high etch selectivity with respect to the oxide layer, so that a residue on the lateral side of a gate electrode can be removed without significantly etching the gate oxide.

14. The method of claim 12, wherein the second gas mixture includes hydrogen bromide (HBr) and O₂.
